(19) United States
(12) Patent Application Publication
(10) Pub. No.: US 2006/0219431 A1
(43) Pub. Date: Oct. 5, 2006

(54) Electronic circuit for high speed signal transmission

(75) Inventor: Manabu Yamazaki, Fuchu (JP)

Correspondence Address: STAAS & HALSEY LLP, SUITE 700, 1201 NEW YORK AVENUE, N.W., WASHINGTON, DC, 20005, US

(73) Assignee: FUJITSU LIMITED, Kawasaki (JP)

(21) Appl. No.: 11/341,590

(22) Filed: Jan. 30, 2006

(30) Foreign Application Priority Data
Mar. 15, 2005 (JP) 2005-073124

(51) Int. Cl. H05K 1/11

(52) U.S. Cl. 174/262

(57) ABSTRACT

An electronic circuit in which a return current path can be acquired effectively, in order to realize high speed signal transmission. The electronic circuit has a first signal layer and a second signal layer, connected with a first via, and at least first and second power supply layers and a grounding layer. A second via, which is electrically connected with only one of the power supply layers or the grounding layer, is located adjacent the first via.

### TECHNICAL FIELD OF THE INVENTION

The present invention relates to an electronic circuit which can realize, for example, high speed signal transmission in units of Gbps and, more particularly, to an electronic circuit which can acquire a return current path, at the time of exchanging the signal among different signal wiring layers.

The present invention will be explained assuming a printed wiring substrate/circuit board used in an information processing apparatus as an electronic circuit.

### RELATED ART

In a circuit board used for an information processing apparatus, one or a plurality of signal wiring layers are formed. In the case of providing a plurality of signal wiring layers in a circuit board, vias for connecting these signal wiring layers are formed in order to allow the signals to flow between the different layers. Moreover, there are formed on the circuit board a power supply layer, to supply power to various electronic components mounted on the circuit board, and a grounding layer. Since some electronic components operate with different power source voltages, a plurality of power supply layers are sometimes formed on the circuit board to supply different operating voltages, suitable for respective electronic components.

When a signal flows in the signal layer formed on the circuit board, a return current flows in the grounding layer and power supply layer in a direction opposing the signal flowing direction.

FIG. 1 is a diagram showing the flow of a return current in the circuit board.

In the circuit board illustrated in FIG. 1, the different signal layers 2 and 3 are connected with a via 1. The signal 7 flows to the right, from the left of the signal layer 3, and also flows to the right, from the left of the signal 2, through via 1. As explained above, connection of signal layers 2 and 3 by via 1 allows the flow of the signal 7 from layer 3 to layer 2.

The circuit board illustrated in FIG. 1 is further provided with power supply layers 4 and 5 and ground layer 6. When the signal 7 flows in signal layers 2 and 3, a return current flows in power supply layers 4 and 5 and grounding layer 6.

When signal 7 flows in signal layer 3, a return current 10 flows in the power supply layer 5. In the same manner, when signal 7 flows into the signal layer 2, the return current 9 flows in the power supply layer 4. In addition, in the example of FIG. 1, the return current 8 also flows in the grounding layer 6 which is sandwiched by the signal layer 2 and signal layer 3.

Here, the return current 8 flowing in the grounding layer 6 is capable of flowing in the same grounding layer 6 when signal 7 flows in signal layer 2 and when signal 7 flows in signal layer 3. However, for the return currents 9 and 10 flowing in the power supply layers 2 and 3, a path of the return current is broken at the area indicated with a mark X. When the return current path is broken, as explained above, transmission loss of the signal flowing in the signal layer increases.

In view of solving the problem caused by breaking the return current path as explained above, a method in which the power supply layer and the grounding layer are coupled with a bypass capacitor has been proposed.

FIGS. 2(A) and (B) are a plan view and a side view, respectively, of a diagram illustrating the conditions of the layout in which a bypass capacitor 11 is arranged in the periphery of a via 1 connecting the signal layer 2 and signal layer 3. Moreover, FIG. 3 is a schematic diagram of the cross-section of the circuit board in which a bypass capacitor is arranged. Flows of respective currents are also illustrated in this figure.

As illustrated in FIG. 3, the bypass capacitor 11 is connected between the power supply layer 4 and the grounding layer 6. In the same manner, a bypass capacitor 12 is also connected between the power supply layer 5 and the grounding layer 6. The bypass capacitors 11 and 12 allow flow of the return current for short-circuiting the power supply layer and the grounding layer.

In the example of FIG. 3, the return current 9 flowing in the power supply layer 4, corresponding to the signal 7 flowing in the signal layer 2 as shown in FIG. 1, flows in the grounding layer 6 via the bypass capacitor 11 with the path 9a. The current flowing into the grounding layer 6 flows into the power supply layer 5 via the bypass capacitor 12 with the path 9b. Accordingly, a return path is formed to connect the power supply layer 4 and power supply layer 5 and breaking of the return current path generated in the example of FIG. 1 can be eliminated. [JP-A No. 1999-233951].

However, the structure, in which the bypass capacitors explained above are provided, has the following problems.

In the example of FIG. 3, the bypass capacitors are provided to connect the power supply layer and the grounding layer. When the number of signal wiring layers used in the circuit board increases, the number of bypass capacitors to be arranged also increases, causing a problem in that the space required for arrangement of bypass capacitors becomes larger.

Moreover, at least the arrangement space for the bypass capacitor is required at the time of arrangement of individual bypass capacitors. Therefore, it is a problem that a region for the wiring of the circuit board is reduced by the arrangement space of the bypass capacitors and a certain restriction is generated in the wiring process.

### SUMMARY OF THE INVENTION

With consideration of such problems, an object of the present invention is to realize an electronic circuit which can effectively acquire a return current path by preventing generation of various restrictions resulting from arrangements of bypass capacitors on the electronic circuit.

The problems explained above may be solved with an electronic circuit in which a first signal layer and a second signal layer are connected with a first via and a power supply layer and a grounding layer are provided, whereas a second via, which is electrically connected with one of the power supply layer and the grounding layer but is not electrically connected with the other of the power supply layer and the grounding layer, is also provided at the area near the first via.

Moreover, the problem explained above may also be solved by providing the second via within a distance of 5 mm from the first via.

In addition, the problem explained above may be solved by providing the second via at a distance of (2n+1)λ/4 from the first via, where λ is the wavelength of the signal flowing in the signal layer and n is an integer greater than or equal to 0.

According to the present invention, a return path of the electronic circuit can be acquired effectively without providing a bypass capacitor and, moreover, transmission loss of signal flowing into the wiring layer can be reduced.

### BRIEF DESCRIPTION OF THE DRAWINGS

FIG. 1 is a schematic diagram showing a flow of return current between layers.

FIGS. 2(A) and 2(B) are a plan view and a side view, respectively, of a diagram illustrating an electronic device provided with a bypass capacitor.

FIG. 3 is a schematic diagram of an electronic device provided with a bypass capacitor.

FIGS. 4(A) and 4(B) are a plan view and a side view, respectively, of a diagram illustrating an electronic device in which a second via is formed, in accordance with an embodiment of the present invention.

FIG. 5 is a schematic diagram of a electronic device in which a vias are formed, in accordance with an embodiment of the present invention.

FIG. 6 is a diagram illustrating the relationship between a via interval and a signal transmission loss value.

### DETAILED DESCRIPTION OF THE PREFERRED EMBODIMENT

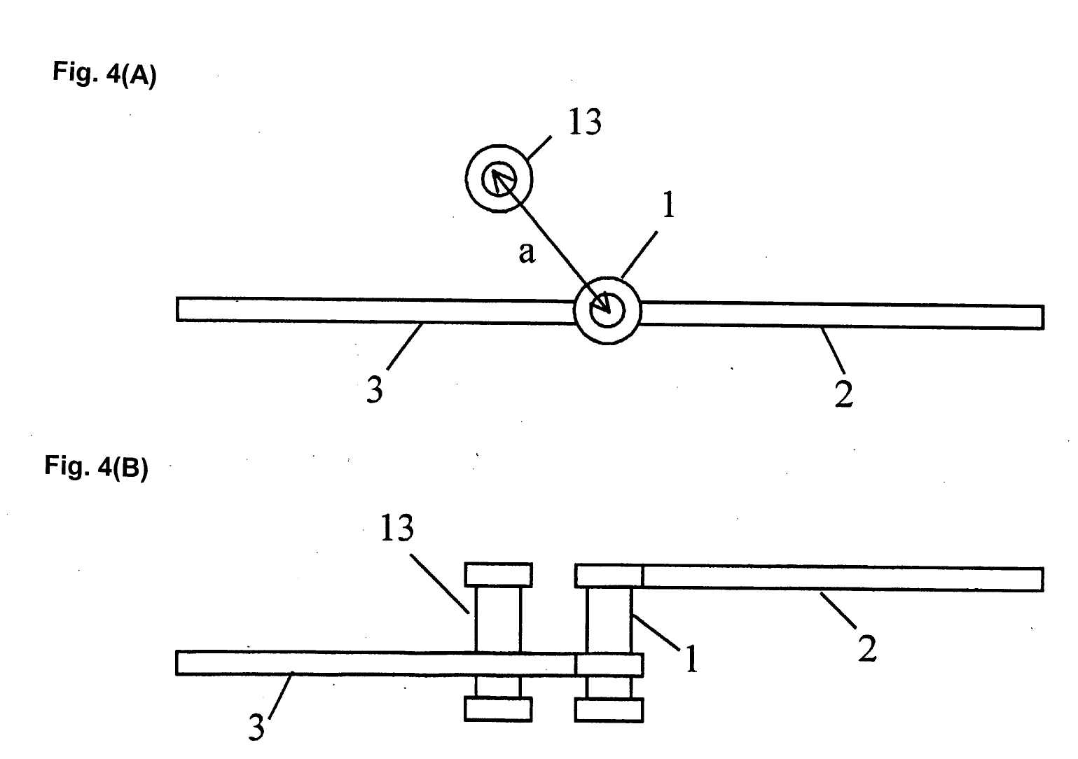

FIGS. 4(A) and 4(B) provide a plan view and a side view, respectively, which illustrate the arrangement of vias on a circuit board. In these figures, numeral 1 denotes a layer exchange via; 2 and 3, signal layers; 13, a via formed between the power supply layer and the grounding layer.

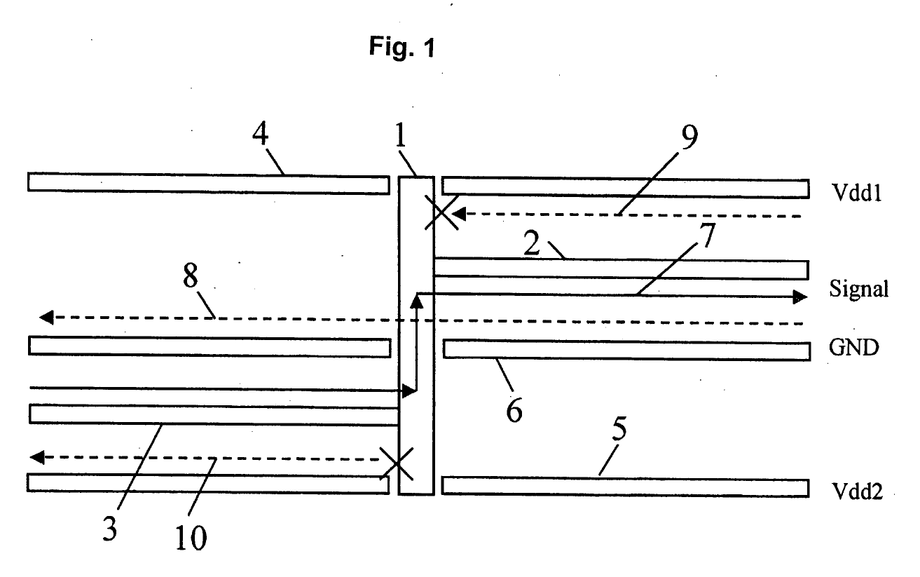

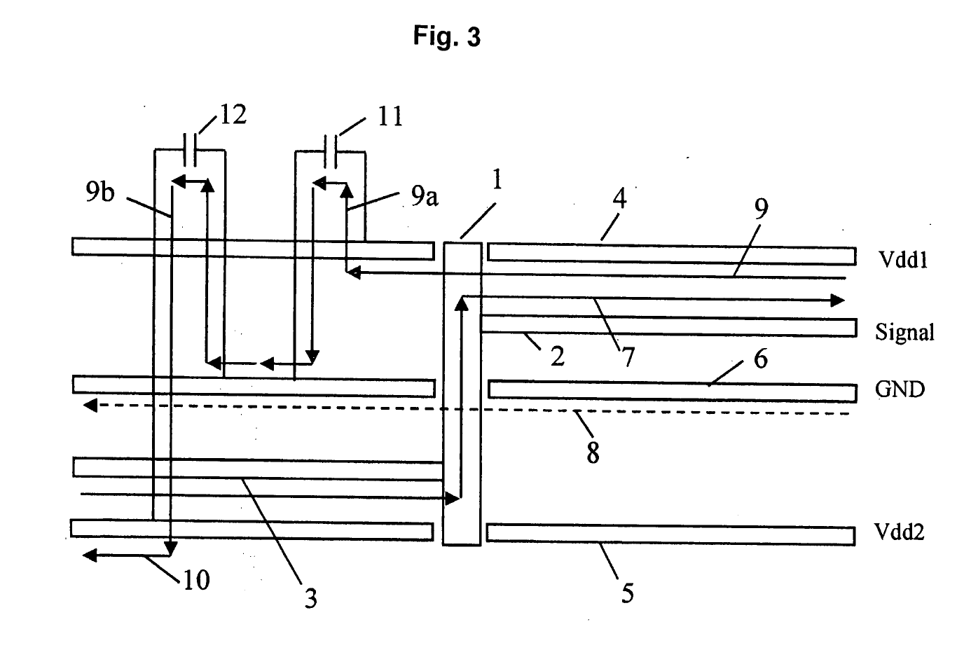

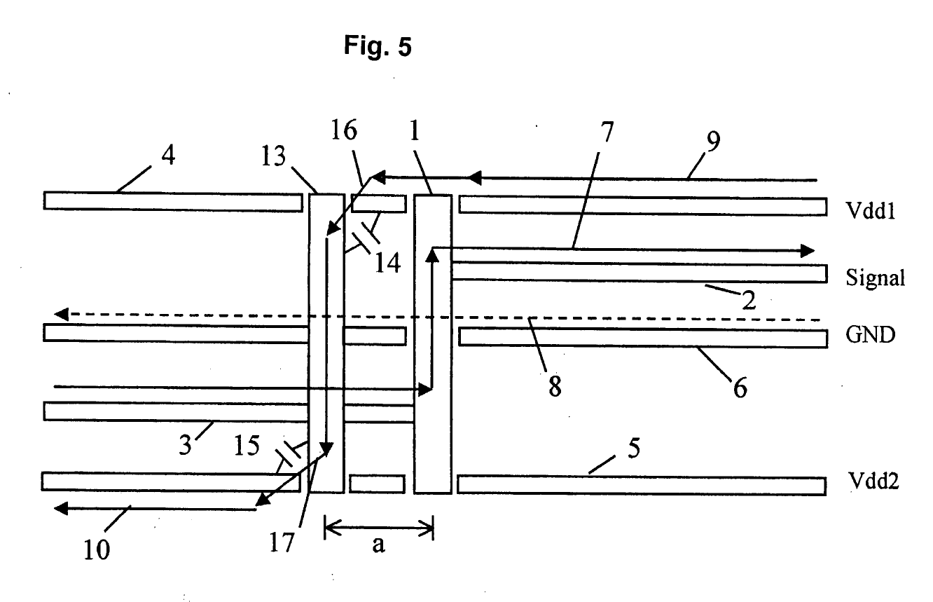

FIG. 5 schematically illustrates a cross-section of the circuit board. In FIG. 5, the structural elements, designated with the same reference numerals of FIG. 1 and FIG. 3, are identical to those in FIG. 1 and FIG. 3. Moreover, in FIG. 5, numeral 13 denotes a via formed between the power supply layer and the grounding layer.

In this embodiment, the via 13 is formed at a distance (a) from the layer exchange via 1. Here, the via 13 is electrically connected with either the power supply layers or the grounding layer, but electrically disconnected from the other of the power supply layers or the grounding layer. In the example of FIG. 5, the via 13 is connected electrically to the grounding layer 6 but is electrically disconnected from the power supply layer 4 and the power supply layer 5. Of course, it is also possible to employ a structure in which the via 13 is electrically connected to the power supply layers 4 and 5 but is electrically disconnected from the grounding layer 6. Moreover, in the example of FIG. 5, the common via 13 is formed for a plurality of power supply layers 4 and 5, but it is also possible to provide a via between the power supply layer 4 and the grounding layer 6 and a different via between the power supply layer 5 and the grounding layer 6. These structures may be selected as required in accordance with the wiring of the circuit board and the mounting of electronic components.

The via 13 and the power supply layer 4 are not electrically connected but a parasitic capacitance 14 is generated between them. In the same manner, a parasitic capacitance 15 is generated between the via 13 and the power supply layer 5. These parasitic capacitances 14 and 15 work like the bypass capacitor illustrated in FIG. 3. Namely, the via 13 and the power supply layer 4 and via 13 and the power supply layer 5 are electrically insulated from the viewpoint of direct current (DC). Meanwhile, the via 13 and the power supply layer 4 and the via 13 and the power supply layer 5 are short-circuited from the viewpoint of alternating current (AC).

Flow of the return current in each power supply layer will be explained with reference to FIG. 5. The return current 9 flowing in the power supply layer 4, corresponding to the signal 7 flowing in the signal layer 2, also flows to the via 13 along the path 16, via the parasitic capacitance 14 generated between the power supply layer 4 and the via 13. Moreover, the current flowing in the via 13 also flows to the power supply layer 5 along the path 17, via the parasitic capacitance 15 generated between the power supply layer 5 and the via 13. Accordingly, breaking of the return current path can be prevented without use of the bypass capacitor.

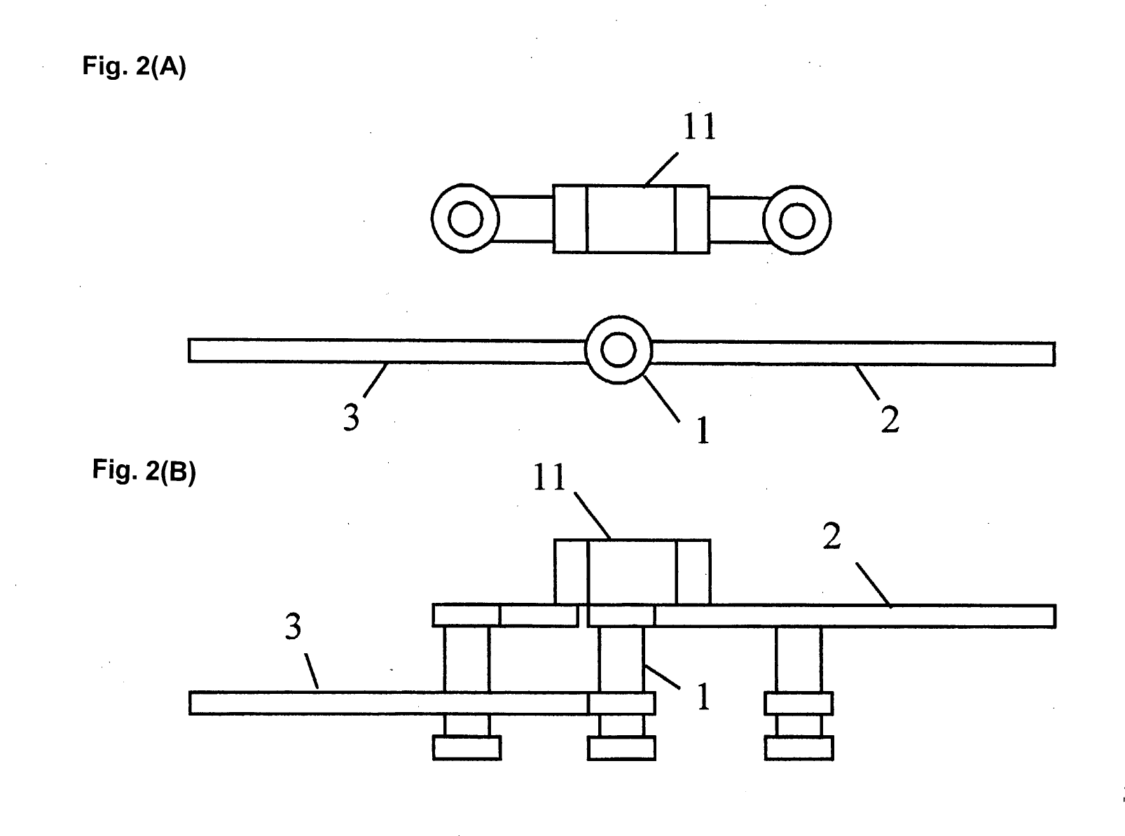

Moreover, as is understood from a comparison of FIGS. 2(A) and 2(B) with FIGS. 4(A) and 4(B), a certain space has been traditionally required for layout of the bypass capacitor, but, in this embodiment of the present invention, a space is required only to form a via through the circuit board. Accordingly, in this embodiment, the region of wiring required for the return path can be reduced, resulting in reduced restrictions for the wiring.

In order to reduce signal transmission loss, attention is paid to an interval between the via 1 and the via 13 (a in FIG. 5).

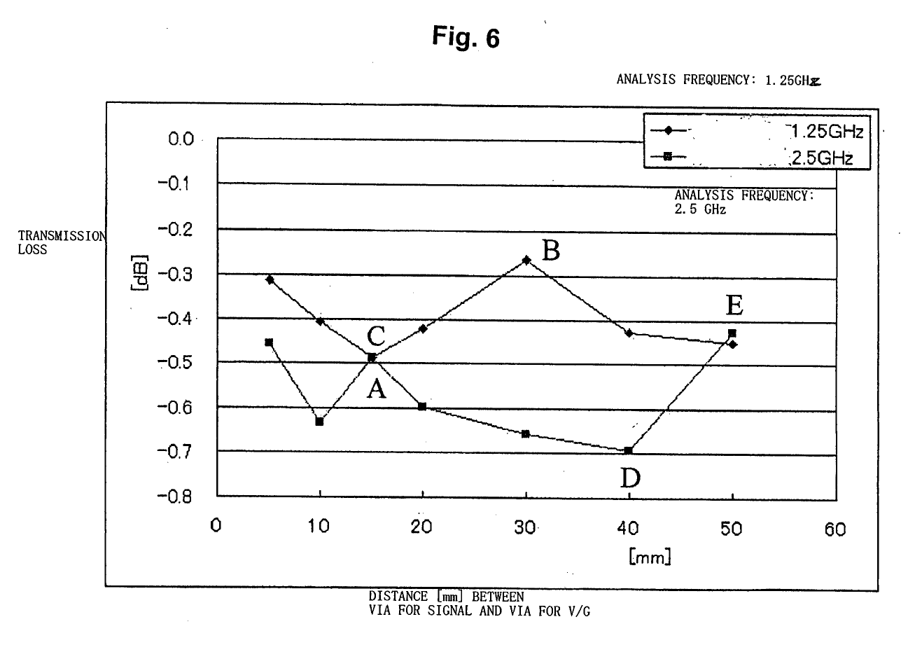

FIG. 6 illustrates the result of simulations to show the relationship between the interval between the via 1 (“via for signal” in FIG. 6) and the via 13 (“via for V/G” in FIG. 6) and signal transmission loss. In FIG. 6, plotting is conducted with an interval of 5 mm in the region where an interval between the via 1 and via 13 is equal to or less than 20 mm, and with an interval of 10 mm in the region where the interval between the via 1 and via 13 is larger than 20 mm. Here, the following conditions are applied to the example of FIG. 6:

Dielectric coefficient of base material εr=4.4

Velocity of light c=3e8(m/s)

Signal frequency=1.25 GHz, 2.5 GHz

Moreover,

Signal transmission velocity v=c/√εr=1.43e(m/s)

Wavelength λ=v/f=104.4(mm)(1.25 GHz)57.2(mm)(2.5 GHz)

Moreover, in the chart of FIG. 6, it is assumed that the closer to 0.0 dB the transmission loss is, namely, the closer to the top of the chart the transmission loss is, the smaller the transmission loss is.

As a result of detail investigations, it has been found that when the interval between the via 1 and via 13 satisfies the relationships of λ/4, 3λ/4, 5λ/4 . . . , the transmission loss is reduced.

For example, when the frequency is 2.5 GHz, the transmission loss becomes small under the condition that λ/4=14.3 mm (near A in FIG. 6). In the same manner, the transmission loss becomes small under the condition that 3λ/4=42.9mm. When the frequency is 1.25 GHz, the transmission loss becomes small under the condition that λ/4=28.6 mm (near B in FIG. 6).

As explained above, it has been found that when the interval between the via 1 and the via 13 is set to a particular value, transmission loss is reduced.

Here, values of transmission loss are compared in the point (B or E in the figure) where the signal transmission loss is small and the point (C or D in the figure) where the signal transmission loss is large. When the frequency is 1.25 GHz, the difference of losses at the points B and C in the figure is about −0.2 db. Similarly, when the frequency is 2.5 GHz, the difference of losses at the points D and E in the figure is about −0.2 db.

When the transmission loss of the circuit board is −15 (db/m), the difference of −0.2 db in the transmission loss value may be used to determine the wiring length as follows:
−0.2(db)/−15(db/m)=about 13 mm

Namely, when the frequency is 2.5 GHz, the wiring length must be reduced by about 13 mm, in the case of the point D, in order to achieve the signal transmission loss value which is identical to that at the point E.

When four vias for layer exchange are provided on a sheet of the circuit board, the difference in the wiring length becomes equal to 13 mm×4=52 mm, in order to acquire the identical transmission loss at the points E and D. Since a difference in the wiring length of 52 mm gives a large influence on the mounting structure of the device, it is very important to determine the interval between the via 1 and the via 13 required to provide a small transmission loss value, in order to allow the appropriate wiring length.

Meanwhile, when the frequency is 1.25 GHz, the transmission loss value tends to be reduced gradually as the interval between the via 1 and the via 13 is reduced gradually from 15 mm. In the same manner, when the frequency is 2.5 GHz, the transmission loss value is reduced as the interval between the via 1 and the via 13 is gradually reduced from about 10 mm.

The difference between the point where the transmission loss value is small and the point (C or D in FIG. 6) where the transmission loss value becomes the maximum, suggests that the transmission loss value is reduced by about −0.2 db in comparison with the maximum transmission loss value at the area near the point where the interval between the via 1 and the via 13 becomes equal to about 5 mm.

That is, when the interval between the via 1 and the via 13 is equal to 5 mm or less, the transmission loss value which is identical to that at the point E or D in FIG. 6 can be attained. Therefore, it is desirable that the via 13 is formed so that the interval between the via 1 and the via 13 is equal to 5 mm or less.

What is claimed is:

1. An electronic circuit, comprising:
a first signal layer and a second signal layer connected through a first via;
power supply and grounding layers; and
a second via, located adjacent to said first via and electrically connected with a selected one of said power supply and grounding layers.

2. The electronic circuit according to claim 1, wherein said second via is located within a distance of 5 mm from said first via.

3. The electronic circuit according to claim 1, wherein;
said second via is located at a distance of (2n+1)λ/4 from said first via, and
λis the wavelength of a signal flowing in the signal layer and n is an integer greater than or equal to 0.

4. The electronic circuit according to claim 1, wherein:
said power supply and grounding layers comprise first and second power supply layers and said grounding layer; and
a return current flows from the first power supply layer to the second power supply layer through the second via.

5. The electronic circuit according to claim 1, wherein:
said power supply and grounding layers comprise first and second power supply layers and said grounding layer; and
said second via is, further, electrically connected to said first power supply layer and the grounding layer.

6. The electronic circuit according to claim 1, wherein:
said power supply and grounding layers comprise first and second power supply layers and said grounding layer; and
said second via is, further, electrically connected between the first and second power supply layers.

7. The electronic circuit according to claim 1, further comprising:
a third via;
said power supply and grounding layers comprise first and second power supply layers and said grounding layer; and
the third via is electrically connected between said second power supply and the grounding layer.

8. The electric circuit according to claim 6, wherein:
a first parasitic capacitance is generated between the first power supply layer and the second via; and
a second parasitic capacitance is generated between the second power supply layer and the second via.
